(19) United States
(12) Patent Application Publication
(10) Pub. No.: US 2025/0149484 A1
(43) Pub. Date: May 8, 2025

(54) SEMICONDUCTOR DEVICE INCLUDING BUMPS AND METHOD OF MANUFACTURING THE SAME

(71) Applicant: SK hynix Inc., Icheon-si Gyeonggi-do (KR)

(72) Inventor: Hyun Chul SEO, Icheon-si Gyeonggi-do (KR)

(73) Assignee: SK hynix Inc., Icheon-si Gyeonggi-do (KR)

(21) Appl. No.: 18/601,215

(22) Filed: Mar. 11, 2024

(30) Foreign Application Priority Data
Nov. 2, 2023 (KR) 10-2023-0150350

(51) Int. Cl. H01L 23/00

(52) U.S. Cl. CPC H01L 24/11; H01L 24/13; H01L 24/16; H01L 24/81; H01L 2224/1146; H01L 2224/13022; H01L 2224/16238; H01L 2224/81191; H01L 2224/81815; H01L 2924/206

(57) ABSTRACT

A semiconductor device including bumps and a method of manufacturing the same. The semiconductor device includes a first pillar and a second pillar formed over a substrate, a first solder layer configured to cover a first surface of the first pillar, and a second solder layer configured to cover a second surface of the second pillar. The first surface of the first pillar has a lower height than a height of the second surface of the second pillar. The second solder layer has a smaller thickness than a thickness of the first solder layer to compensate for a difference between a height of the second surface and a height of the first surface.

### CROSS-REFERENCE TO RELATED APPLICATION

The present application claims priority under 35 U.S.C. § 119 (a) to Korean Patent Application No. 10-2023-0150350, filed in the Korean Intellectual Property Office on Nov. 2, 2023, the entire disclosure of which is incorporated herein by reference.

### BACKGROUND

The present disclosure relates to semiconductor package technology, and particularly, to a semiconductor device including bumps and a method of manufacturing the same.

A conductive bump structure is adopted for a semiconductor device or a technology for packaging a semiconductor device. In order to electrically connect an integrated circuit integrated in a semiconductor substrate to a device outside of the semiconductor device, a semiconductor device in which conductive bumps are formed in a connecting pad of the semiconductor substrate is known. Because operation of the semiconductor device at a high speed and with a smaller form factor is advantageous, an electrical connection method through bumps is adopted for many semiconductor devices. The conductive bump structure may connect a semiconductor device and a packaging substrate or may connect a semiconductor device and another semiconductor device.

### SUMMARY

In an embodiment, a semiconductor device may include a first pillar and a second pillar formed over a substrate, a first solder layer configured to cover a first surface of the first pillar, and a second solder layer configured to cover a second surface of the second pillar. The first surface of the first pillar has a lower height than a height of the second surface of the second pillar, and the second solder layer has a smaller thickness than a thickness of the first solder layer to compensate for a difference between a height of the second surface and a height of the first surface, wherein the first surface of the first pillar is a surface of the first pillar at a farthest distance from a surface of the substrate, and the second surface of the second pillar is a surface of the second pillar at a farthest distance from the surface the substrate.

In an embodiment, a semiconductor device may include a first substrate and a second substrate that is disposed over the first substrate and that includes a first conductive trace and a second conductive trace, a first pillar and a second pillar disposed between the first substrate and the second substrate, a first solder layer configured to cover a first surface of the first pillar, and a second solder layer configured to cover a second surface of the second pillar. The first surface of the first pillar may be disposed at a lower height than a height of the second top surface of the second pillar. The first surface of the first pillar may be a surface of the first pillar at a farthest distance from a surface of the substrate, and the second surface of the second pillar may be a surface of the second pillar at a farthest distance from the surface the substrate. The first solder layer may be connected to the first conductive trace. The second solder layer may be connected to the second conductive trace. A distance between the first surface and the first conductive trace may be greater than a distance between the second surface and the second conductive trace.

In an embodiment, a method of manufacturing a semiconductor device may include forming a first pillar and a second pillar over a substrate, forming a first resist pattern including a first opening that exposes a first surface of the first pillar and comprising a second opening that exposes a second surface of the second pillar and that has a smaller width than the width of the first opening, wherein the first surface of the first pillar is a surface of the first pillar at a farthest distance from a surface of the substrate, and the second surface of the second pillar is a surface of the second pillar at a farthest distance from the surface the substrate, forming a first solder pattern within the first opening and a second solder pattern within the second opening, removing the first resist pattern, and forming a first solder layer by reflowing the first solder pattern, and forming a second solder layer by reflowing the second solder pattern.

A semiconductor device comprising a first pillar and a second pillar formed over a substrate; a first solder layer configured to cover a first surface of the first pillar; and a second solder layer configured to cover a second surface of the second pillar. The second solder layer may have a smaller thickness than a thickness of the first solder layer to compensate for a difference between a height of the second surface and a height of the first surface.

### BRIEF DESCRIPTION OF THE DRAWINGS

FIG. 1 through FIG. 4 are cross-sectional views illustrating semiconductor devices according to embodiments.

FIG. 5 through FIG. 13 are cross-sectional views illustrating a semiconductor device formed utilizing a method of manufacturing the semiconductor device according to an embodiment.

FIG. 14 is a cross-sectional view illustrating a semiconductor device according to an embodiment.

### DETAILED DESCRIPTION

Terms that are used in the description of the present disclosure are terms selected by taking into consideration functions in proposed embodiments, and the meanings of the terms may be different depending on a user, an operator's intention, or practice in the technical field. The meaning of a term is included in the definition of the term if the term is specifically defined in this specification and may be a meaning that is commonly recognized by those skilled in the art if the term is not specifically defined.

In the description of the present disclosure, terms, such as “first,” “second,” “bottom,” “top,” “topmost,” “side,” and “lower,” are used to distinguish components from each other for the ease of description and are not intended to limit the components themselves or to indicate specific order or relation. In the description of the present disclosure, terms such as “on or over” or “under or beneath” indicate a relative positional relationship and are not limited to a specific case in which one component is in direct contact with another component or a third component is located between the two components. The same interpretation may be applied to other expressions that describe a positional relationship between component.

Throughout this specification, the same reference numerals denote the same or similar components. Although not mentioned or described in a corresponding drawing, the same reference numerals or similar reference numerals may be described with reference to another drawing. Furthermore, although a reference numeral is not indicated in a portion of a corresponding drawing, the reference numeral may be described with reference to another drawing. The cross-hatching throughout the figures illustrates corresponding or similar areas between the figures rather than indicating the materials for the areas.

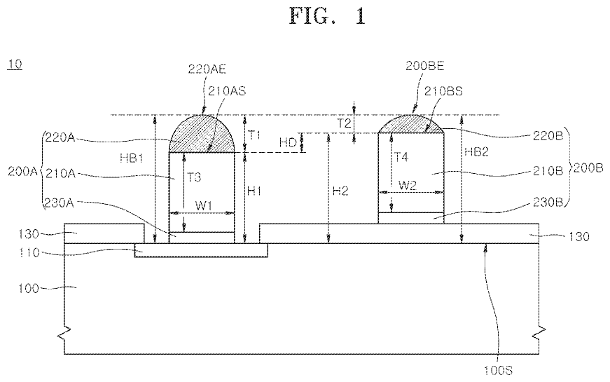

FIG. 1 is a cross-sectional view illustrating a semiconductor device 10 according to embodiments. Referring to FIG. 1, the semiconductor device 10 includes a substrate 100, a first pillar 210A, a second pillar 210B, a first solder layer 220A, and a second solder layer 220B. The substrate 100 may be a semiconductor chip or a semiconductor wafer. The substrate 100 may include a semiconductor substrate in which an integrated circuit (not illustrated) is integrated. The integrated circuit may include electronic elements, such as a transistor, and an interconnection wiring structure that connects the electronic elements. The integrated circuit may comprise a memory device, such as DRAM or NAND flash.

The substrate 100 includes a conductive pad 110 at a surface 100S. The conductive pad 110 may include a metal layer. The metal layer may include aluminum (Al). The conductive pad 110 may be electrically connected to an integrated circuit. The conductive pad 110 may be a connection terminal that electrically connects the integrated circuit of the semiconductor device 10 to an external device. The conductive pad 110 may be an input/output (I/O) terminal. The semiconductor device 10 includes a dielectric layer 130 that covers the surface 100S of the substrate 100 and that exposes the conductive pad 110. The dielectric layer 130 may be a passivation layer or a protecting layer. The dielectric layer 130 may include a polymeric layer. The polymeric layer may include a polyimide, such as polyimide Isoindro quindzoline (PIQ).

The first pillar 210A and the second pillar 210B are spaced apart from each other and disposed over the substrate 100. The first pillar 210A is electrically connected to the conductive pad 110 of the substrate 100. A first underlying layer 230A of the first pillar 210A is disposed between the first pillar 210A and the conductive pad 110. The second pillar 210B is connected to the dielectric layer 130. A second underlying layer 230B is disposed between the second pillar 210B and the dielectric layer 130. The first underlying layer 230A and the second underlying layer 230B may be metal layers having substantially the same thickness. The first underlying layer 230A and the second underlying layer 230B may each be an under-bump metallurgy (UBM) layer. The second pillar 210B and the second underlying layer 230B overlap the dielectric layer 130. The second pillar 210B is electrically isolated from the substrate 100 by the dielectric layer 130. The second pillar 210B is electrically isolated from the integrated circuit of the substrate 100 by the dielectric layer 130.

The first pillar 210A and the second pillar 210B may include substantially the same conductive material(s). The first pillar 210A and the second pillar 210B may include the same materials simultaneously formed by a single process. The first pillar 210A and the second pillar 210B may each include a metal material that is formed by a plating process. The first pillar 210A and the second pillar 210B may each be a metal layer including copper (Cu). The first pillar 210A and the second pillar 210B may each have a cylindrical shape. In another embodiment, the first pillar 210A and the second pillar 210B may each have different shapes such as a square pillar.

The first solder layer 220A covers a first top surface 210AS of the first pillar 210A. The second solder layer 220B covers a second top surface 210BS of the second pillar 210B. For example, the first top surface 210AS of the first pillar 210A is a surface of the first pillar 210A at a farthest distance from the surface 100S of the substrate 100, and the second top surface 210BS of the second pillar 210B is a surface of the second pillar 210B at a farthest distance from the surface 100S of the substrate 100. The first solder layer 220A and the second solder layer 220B may include the same soldering material. The soldering material may include tin (Sn) and/or silver (Ag). The first solder layer 220A and the second solder layer 220B may be simultaneously formed by a single process and may each include a material having the same composition. The first solder layer 220A and the second solder layer 220B may each include a metal material that is formed by a plating process.

The first solder layer 220A is thicker than the second solder layer 220B. The first solder layer 220A has a first thickness T1. The second solder layer 220B has a second thickness T2 smaller than the first thickness T1. The thickness of the first solder layer 220A, the first thickness T1, indicates a distance from the first top surface 210AS of the first pillar 210A to a topmost end 220AE of the first solder layer 220A. The thickness of the second solder layer 220B, the second thickness T2, indicates a distance from the second top surface 210BS of the second pillar 210B to a topmost end 220BE of the second solder layer 220B. For example, a topmost end 220AE of the first solder layer 220A is an end of the first solder layer 220A farthest from the first pillar 200A, and a topmost end 220BE of the second solder layer 220B is an end of the second solder layer 220A farthest from the second pillar 200B.

A first bump 200A includes the first pillar 210A and the first solder layer 220A. The first bump 200A may further include the first underlying layer 230A. A second bump 200B includes the second pillar 210B and the second solder layer 220B. The second bump 200B may further include the second underlying layer 230B. The second bump 200B overlaps the dielectric layer 130 and is coupled or connected to the dielectric layer 130. The second bump 200B is a dummy bump because the second bump 200B is electrically isolated from the substrate 100 and the integrated circuit of the substrate 100 by the dielectric layer 130. The dummy bump is not electrically connected to the substrate 100 or the integrated circuit but is an element having a bump shape.

The first pillar 210A has a first lateral width W1 and a third longitudinal thickness T3. The second pillar 210B has a second lateral width W2 and a fourth longitudinal thickness T4. When the first pillar 210A and the second pillar 210B are each cylindrical, the first lateral width W1 and the second lateral width W2 indicate the diameters of the first pillar 210A and the second pillar 210B, respectively. The first pillar 210A and the second pillar 210B may have substantially the same features. The first lateral width W1 of the first pillar 210A and the second lateral width W2 of the second pillar 210B may have substantially the same measurement. The third thickness T3 of the first pillar 210A and the fourth thickness T4 of the second pillar 210B may have substantially the same measurement. In another embodiment, the measurements of first pillar 210A and the second pillar 210B are not limited to the aforementioned measurements.

The first top surface 210AS of the first pillar 210A is disposed at a lower height H1 than the height H2 of the second top surface 210BS of the second pillar 210B. The first pillar 210A is disposed to overlap the conductive pad 110, whereas the second pillar 210B is disposed to overlap the dielectric layer 130. Unlike the second pillar 210B, the first pillar 210A is disposed in an opening of the dielectric layer 130. Accordingly, although the third thickness T3 of the first pillar 210A and the fourth thickness T4 of the second pillar 210B are substantially the same, the second top surface 210BS of the second pillar 210B may be disposed higher than the first top surface 210AS of the first pillar 210A by the thickness of the dielectric layer 130. Due to the thickness of the dielectric layer 130, the second top surface 210BS of the second pillar 210B is disposed farther from the substrate 100 than the first top surface 210AS of the first pillar 210A.

The first height H1 of the first top surface 210AS of the first pillar 210A is a distance from the surface 100S of the substrate 100 to the first top surface 210AS. The second height H2 of the second top surface 210BS of the second pillar 210B is a distance from the surface 100S of the substrate 100 to the second top surface 210BS. The first height H1 of the first top surface 210AS of the first pillar 210A may be smaller than the second height H2 of the second top surface 210BS of the second pillar 210B. A difference HD between the height H1 of the first top surface 210AS of the first pillar 210A and the height H2 of the second top surface 210BS of the second pillar 210B may be compensated for when the first solder layer 220A has a thickness T1 that is different from the thickness T2 of the second solder layer 220B. Accordingly, a third height HB1 of the first topmost end 220AE of the first solder layer 220A and a fourth height HB2 of the second topmost end 220BE of the second solder layer 220B are substantially the same.

The third height HB1 of the first topmost end 220AE of the first solder layer 220A is a distance from the surface 100S of the substrate 100 to the first topmost end 220AE. The third height HB1 of the first topmost end 220AE of the first solder layer 220A is the height of the first bump 200A. The fourth height HB2 of the second topmost end 220BE of the second solder layer 220B is a distance from the surface 100S of the substrate 100 to the second topmost end 220BE. The fourth height HB2 of the second topmost end 220BE of the second solder layer 220B is the height of the second bump 200B. As described above, although locations at which the first bump 200A and the second bump 200B are disposed on the substrate 100 are different from each other and underlying structures that are disposed under the first bump 200A and the second bump 200B are different from each other, the height HB1 of the first bump 200A is substantially the same as the height HB2 of the second bump 200B.

If the height of the first bump 200A is different from the height HB2 of the second bump 200B, when the first bump 200A and the second bump 200B are coupled to another substrate or other elements, a failure in which the first bump 200A or the second bump 200B is not coupled to another substrate or other elements without coming into contact with another substrate or other elements due to a difference between the heights of the first bump 200A and the second bump 200B may occur. According to the present disclosure, a failure in which the first bump 200A and the second bump 200B are not coupled to another substrate or other elements because the first bump 200A and the second bump 200B do not come into contact with another substrate or the other elements may be reduced because the height HB1 of the first bump 200A is substantially the same as the height HB2 of the second bump 200B.

The first underlying layer 230A has substantially the same width W1 as the first pillar 210A. The second underlying layer 230B has substantially the same width W2 as the second pillar 210B. The second underlying layer 230B may have substantially the same width as the first underlying layer 230A because the first underlying layer 230A and the second underlying layer 230B are formed when the first pillar 210A and the second pillar 210B are formed having the same width. Accordingly, the second underlying layer 230B may have a bonding surface having substantially the same area as the bonding surface of the first underlying layer 230A. The first bump 200A and the second bump 200B according to the present embodiment may have substantially the same heights HB1 and HB2 despite a difference between the heights of the underlying structures attributable to the dielectric layer 130. Furthermore, areas where the first bump 200A and the second bump 200B are bonded to the underlying structures may be maintained substantially identically. According to the present disclosure, regardless of the underlying structures of the first bump 200A and the second bump 200B, another substrate or element and the substrate 100 may be stably connected. The first bump 200A and the second bump 200B may cover the same size areas where the first bump 200A and the second bump 200B are bonded to the underlying structures and may each maintain the ability to be connected to another substrate or element. A plurality of first bumps 200A and a plurality of second bumps 200B may be implemented.

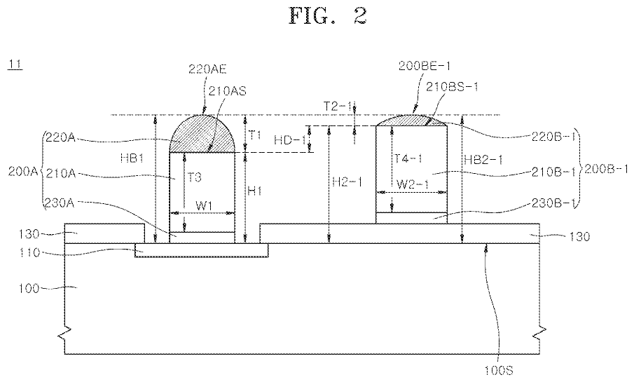

FIG. 2 is a cross-sectional view illustrating a semiconductor device 11 according to an embodiment. In FIG. 2, the same reference numerals used in FIG. 1 indicate the same element or measurement. Referring to FIG. 2, the semiconductor device 11 includes a substrate 100, a first bump 200A, and a second bump 200B-1. The first bump 200A includes a first pillar 210A, a first solder layer 220A, and a first underlying layer 230A. The first bump 200A is connected to a conductive pad 110 of the substrate 100 and is electrically connected to an integrated circuit that is integrated within the substrate 100. The second bump 200B-1 is a dummy bump that is connected to the dielectric layer 130. The second bump 200B-1 includes a second pillar 210B-1, a second solder layer 220B-1, and a second underlying layer 230B-1.

The second pillar 210B-1 has a second lateral width W2-1 greater than the first lateral width W1 of the first pillar 210A and has a fourth thickness T4-1 greater than the third thickness T3 of the first pillar 210A. The second solder layer 220B-1 has a second thickness T2-1 that is a distance from a second top surface 210BS-1 of the second pillar 210B-1 to a second topmost end 220BE-1 of the second solder layer 220B-1. The second thickness T2-1 is smaller than a first thickness T1 of the first solder layer 220A. A first height H1 of the first top surface 210AS of the first pillar 210A and a second height H2-1 of the second top surface 210BS-1 of the second pillar 210B-1 are different due to a difference between the thickness of the dielectric layer 130 and the difference between the thickness of the first pillar 210A and the thickness of second pillar 210B-1. A difference between the second thickness T2-1 of the second solder layer 220B-1 and the first thickness T1 of the first solder layer 220A may be compensated for by a difference HD-1 between the first height H1 and the second height H2-1. Accordingly, the first bump 200A may have the same height as the second bump 200B-1.

The height HB2-1 of the second bump 200B-1 the height HB1 of the first bump 200A are substantially the same, but the second lateral width W2-1 of the second pillar 210B-1 of the second bump 200B-1 is greater than the first lateral width W1 of the first pillar 210A. The width W2-1 of the second underlying layer 230B-1, having substantially the same width W2-1 as the second pillar 210B-1, is greater than the width W1 of the first underlying layer 230A, having substantially the same width W1 as the first pillar 210A. Accordingly, an area where the second underlying layer 230B-1 and the dielectric layer 130 are connected is greater than an area where the first underlying layer 230A and the conductive pad 110 are connected. Coupling power between the second underlying layer 230B-1 and the dielectric layer 130 may be smaller than coupling power between pieces of metal of the first underlying layer 230A and the conductive pad 110 because the second underlying layer 230B-1 includes a metallic material and the dielectric layer 130 includes a dielectric material or a polymer material. Weak coupling power between a metallic material and a non-metallic material may be compensated for because the area in which the second underlying layer 230B-1 and the dielectric layer 130 are connected is greater than the area where the first underlying layer 230A and the conductive pad 110 are connected. Accordingly, a failure in which the second bump 200B-1 is detached from or broken away from the dielectric layer 130 may be reduced because the second bump 200B-1 may be more strongly connected to the dielectric layer 130 over the larger area.

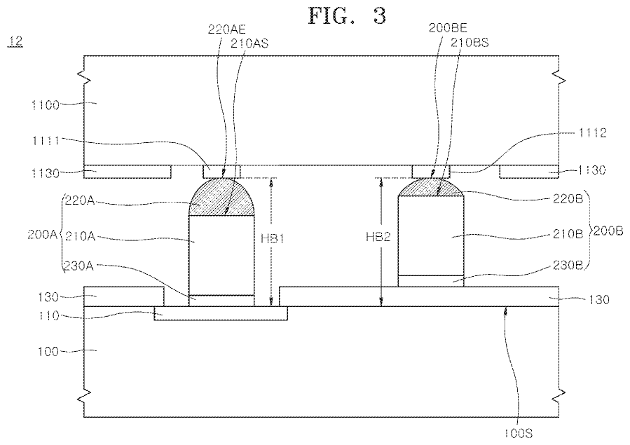

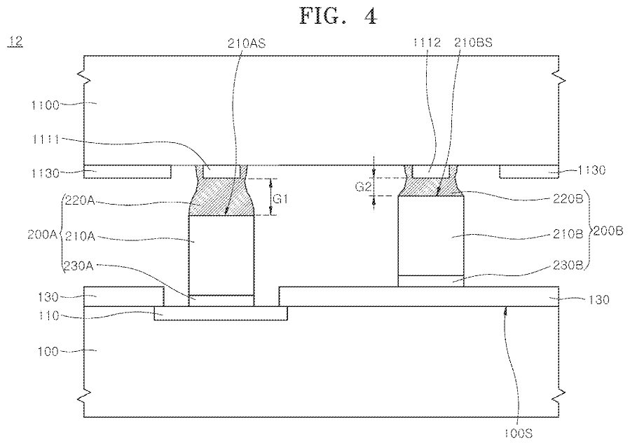

FIG. 3 and FIG. 4 are cross-sectional views illustrating a semiconductor device 12 during a process of forming the semiconductor device 12 according to embodiments. FIG. 4 illustrates a bump fastening structure in which solder layers 220A and 220B in FIG. 3 are connected through a reflow process. The same reference numerals in FIG. 1 and FIG. 2 indicate the same element or measurement in FIG. 3 and FIG. 4. In FIG. 3 and FIG. 4, the first substrate 100 is substantially the same element as the substrate 100 in FIG. 1 and FIG. 2.

Referring to FIG. 3, a second substrate 1100 is stacked on or over the first substrate 100 or the first substrate 100 is stacked on or over the second substrate 1100, resulting in the semiconductor device 12. The semiconductor device 12 is a semiconductor package in which the first substrate 100 and the second substrate 1100 are connected by the first bump 200A and the second bump 200B. The second bump 200B of FIG. 1 or the second bump 200B-1 in FIG. 2 may be utilized in the embodiment of FIG. 3 and FIG. 4.

The second substrate 1100 may be a semiconductor substrate in which an integrated circuit is integrated. Alternatively, the second substrate 1100 may be a packaging substrate. The packaging substrate may be a printed circuit board (PCB) on which a semiconductor substrate, a semiconductor chip, and/or other electronic devices are mounted. The second substrate 1100 may be an interconnection structure in which wires are stacked. The second substrate 1100 may be an interposer. The second substrate 1100 might not be limited to a specific form or a specific element when the second substrate 1100 is an element to which the first bump 200A and the second bump 200B of the first substrate 100 are connected. The second substrate 1100 includes a first conductive trace 1111 and a second conductive trace 1112 that are spaced apart from each other. The second substrate 1100 is disposed over the first substrate 100 such that the first conductive trace 1111 and second conductive trace 1112 face the first substrate 100. The first conductive trace 1111 is connected to the first solder layer 220A. The second conductive trace 1112 is connected to the second solder layer 220B. A protection layer 1130 that protects a surface of the second substrate 1100 by covering the surface while exposing the first conductive trace 1111 and the second conductive trace 1112 to the second substrate 1100 may be additionally formed. The protection layer 1130 may include a dielectric material or a polymer material.

FIG. 3 illustrates a state in which the second substrate 1100 is disposed on the first bump 200A and the second bump 200B of the first substrate 100 or illustrates a state in which the first substrate 100 is disposed on the second substrate 1100 such that the first bump 200A and the second bump 200B of the first substrate 100 come into contact with the second substrate 1100. When the first top surface 210AS of the first pillar 210A of the first bump 200A is disposed at a lower height than the second top surface 210BS of the second pillar 210B of the second bump 200B, a difference between the heights of the first top surface 210AS and the second top surface 210BS may be compensated for when the second solder layer 220B has a smaller thickness than the thickness of the first solder layer 220A. Both the first solder layer 220A and the second solder layer 220B contact the first conductive trace 1111 and the second conductive trace 1112 disposed on the second substrate 1100, respectively, because the first bump 200A and the second bump 200B have substantially the same height. When a reflow process is performed such that solder materials of the first solder layer 220A and the second solder layer 220B are melted by applying heat to the first solder layer 220A and the second solder layer 220B, the first solder layer 220A and the second solder layer 220B are connected to the conductive traces 1111 and 1112 by covering the conductive traces 1111 and 1112 with the solder materials as illustrated in FIG. 4.

Referring to FIG. 4, when the first bump 200A and the second bump 200B are connected to the first conductive trace 1111 and the second conductive trace 1112, respectively, a first separation distance G1 between the first conductive trace 1111 and the first top surface 210AS of the first pillar 210A may be greater than a second separation distance G2 between the second conductive trace 1112 and the second top surface 210BS of the second pillar 210B. The first solder layer 220A may have a greater volume than the second solder layer 220B because the first solder layer 220A is thicker than the second solder layer 220B as illustrated in FIG. 3. The first solder layer 220A may be reflowed to cover the first conductive trace 1111 while filling the gap having the first separation distance G1 between the first conductive trace 1111 and the first pillar 210A. Accordingly, if the first top surface 210AS of the first pillar 210A is disposed at a lower height than the second top surface 210BS of the second pillar 220A, the first solder layer 220A may be stably connected to the first conductive trace 1111.

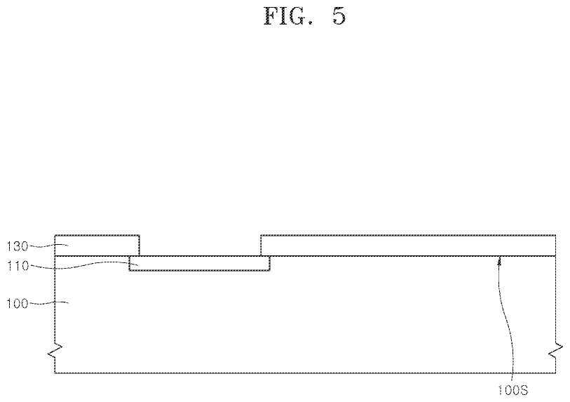

FIG. 5 through FIG. 12 are cross-sectional views illustrating a semiconductor device formed utilizing a method of manufacturing the semiconductor device according to an embodiment. In FIG. 5 through FIG. 12, the same reference numerals used in FIG. 1 and FIG. 2 indicate the same elements or measurements.

Referring to FIG. 5, the dielectric layer 130 is formed on the substrate 100. The substrate 100 includes the conductive pad 110 that is formed at the surface 100S of the substrate 100 in this example. The dielectric layer 130 may be formed to cover the surface 100S of the substrate 100 while exposing a section of the conductive pad 110.

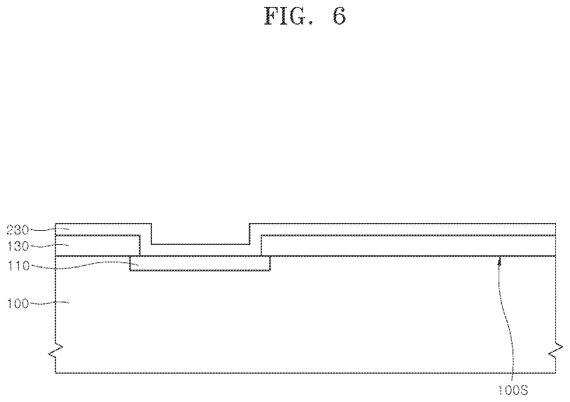

Referring to FIG. 6, an underlying layer 230 is formed on the substrate 100. The underlying layer 230 may be formed of an under-bump metallurgy (UBM) layer. The underlying layer 230 may be a seed layer for plating, which grows a plating layer in a plating process. The seed layer for plating may cover the conductive pad 110 and may extend to cover the dielectric layer 130.

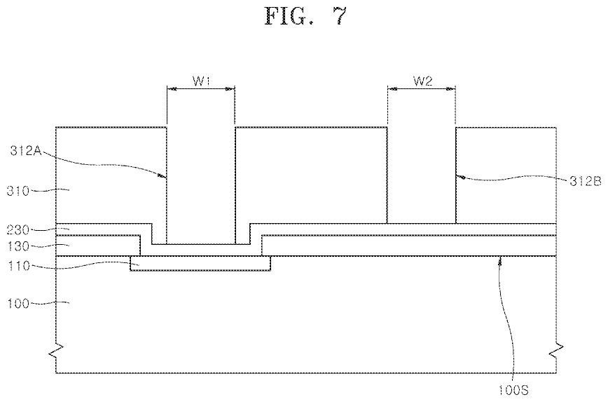

Referring to FIG. 7, a first resist pattern 310 is formed on the underlying layer 230 of the substrate 100. The first resist pattern 310 may be formed as a template or a plating resist pattern in a plating process. The first resist pattern 310 is formed as a pattern that includes a first opening 312A and a second opening 312B. The first resist pattern 310 may be formed by a process of forming a layer including a resist material on the substrate 100 and exposing and developing the layer of the resist material.

The first opening 312A of the first resist pattern 310 overlaps the conductive pad 130. The second opening 312B of the first resist pattern 310 overlaps the dielectric layer 130. The first opening 312A and second opening 312B of the first resist pattern 310 are each a through hole that exposes a part of the underlying layer 230. The first opening 312A and second opening 312B of the first resist pattern 310 may have substantially the same width or diameter. The second opening 312B of the first resist pattern 310 may have a greater width or diameter than the width or diameter of the first opening 312A. A second lateral width W2 of the second opening 312B of the first resist pattern 310 may have the same measurement as a first lateral width W1 of the first opening 312A or may have a greater measurement than the first lateral width W1 of the first opening 312A.

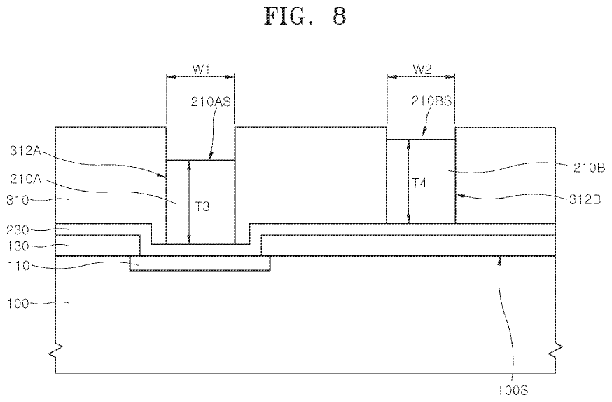

Referring to FIG. 8, a plating process including growing metal layers within the first opening 312A and second opening 312B of the first resist pattern 310 is performed. A metal material is plated from portions of the underlying layer 230, which are exposed to the bottoms of the first opening 312A and second opening 312B of the first resist pattern 310. By growing the metal layers within the openings 312A and 312B, the first pillar 210A may be formed within the first opening 312A of the first resist pattern 310, and the second pillar 210B may be formed within the second opening 312B of the first resist pattern 310. When the second lateral width W2 of the second opening 312B of the first resist pattern 310 has the same measurement as the first lateral width W1 of the first opening 312A, the third thickness T3 of the first pillar 210A may be formed substantially identically to the fourth thickness T4 of the second pillar 210B. When the second lateral width W2 of the second opening 312B of the first resist pattern 310 is greater than the first lateral width W1 of the first opening 312A, the fourth thickness T4 of the second pillar 210B may be formed with a greater or larger thickness than the third thickness T3 of the first pillar 210A. The second top surface 210BS of the second pillar 210B is disposed higher than the first top surface 210AS of the first pillar 210A by the thickness of the dielectric layer 130 because the dielectric layer 130 overlaps the second pillar 210B and not the first pillar 210A. After the first pillar 210A and the second pillar 210B are formed, the first resist pattern 310 is removed.

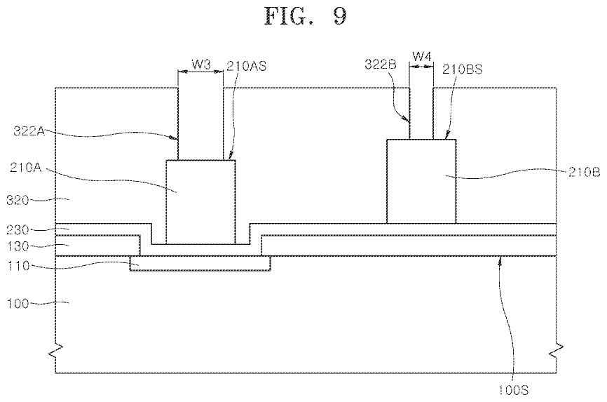

Referring to FIG. 9, a second resist pattern 320 is formed over the substrate 100. The second resist pattern 320 is formed as a pattern that covers the underlying layer 230 and that includes a third opening 322A and a fourth opening 322B. The third opening 322A of the second resist pattern 320 is a through-hole that exposes a part of the top surface 210AS of the first pillar 210A. The fourth opening 322B of the second resist pattern 320 is a through-hole that exposes a part of the top surface 210BS of the second pillar 210B. The fourth opening 322B may be formed having a smaller width than the width of the third opening 322A. A fourth width W4 of the fourth opening 322B has a smaller value than a third width W3 of the third opening 322A in the example of FIG. 9.

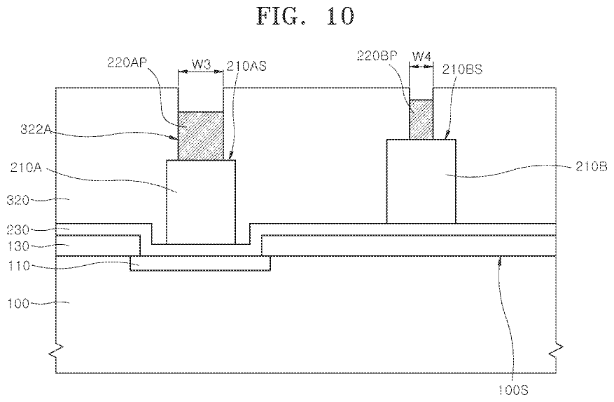

Referring to FIG. 10, a first solder pattern 220AP is formed within the third opening 322A of the second resist pattern 320. A second solder pattern 220BP is formed within the fourth opening 322B of the second resist pattern 320. The layers of solder materials may be grown by a plating process from the first top surface 210AS of the first pillar 210A, which is exposed through the third opening 322A of the second resist pattern 320, and the second top surface 210BS of the second pillar 210B, which is exposed through the fourth opening 322B. The first solder pattern 220AP that is plated may be formed having a greater volume than the volume of the second solder pattern 220BP because the third width W3 of the third opening 322A is greater than the fourth width W3 of the fourth opening 322B.

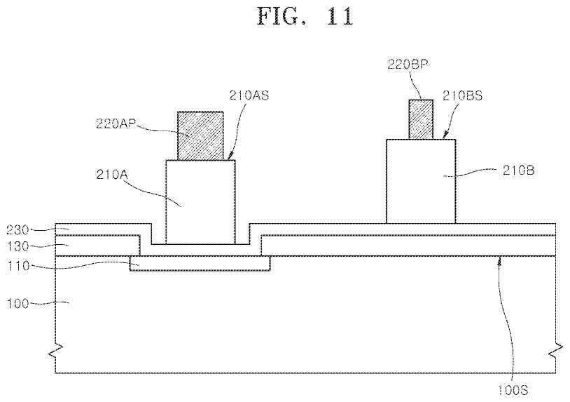

Referring to FIG. 11, after the first solder pattern 220AP and the second solder pattern 220BP are formed, the second resist pattern (320 in FIG. 10) is removed in this example.

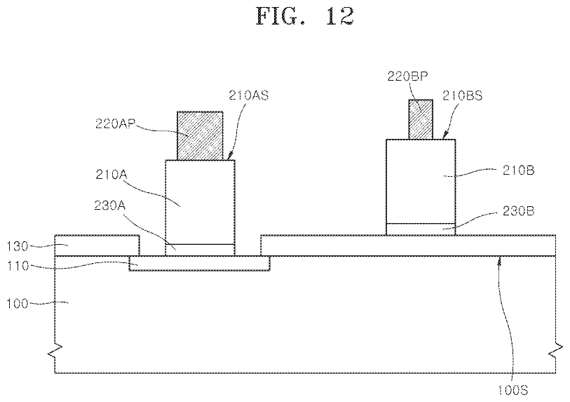

Referring to FIG. 11 and FIG. 12, portions of the underlying layer 230 that are exposed without overlapping the first pillar 210A and the second pillar 230B is removed, leaving the first underlying layer 230A between the first pillar 210A and the conductor 110 and the second underlying layer 230B between the second pillar 210B and the dielectric layer 130. As described above, the first underlying layer 230A that overlaps the first pillar 210A and the second underlying layer 230B that overlaps the second pillar 230B are formed.

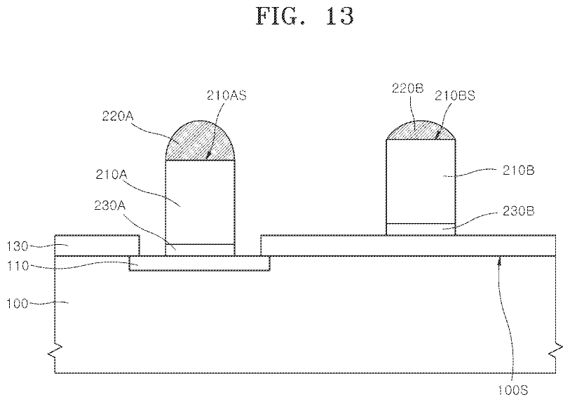

Referring to FIG. 12 and FIG. 13, the first solder layer 200A and the second solder layer 200B are formed by reflowing the first solder pattern 220AP and the second solder pattern 220BP, respectively. The first top surface 210AS of the first pillar 210A, which is exposed, may be covered as the solder material of the first solder pattern 220AP is melted, and is deformed into the first solder layer 220A having an elliptical shape in this embodiment. The second top surface 210BS of the second pillar 210B, which is exposed, may be covered as the solder material of the second solder pattern 220BP is melted, and is deformed into the second solder layer 220B having an elliptical shape in this embodiment. The second solder layer 220B is formed having a smaller thickness than the thickness of the first solder layer 220A. Because the area of the second top surface 210BS of the second pillar 210B and the area of the first top surface 210AS of the first pillar 210A are substantially the same when the widths/diameters of the pillars 210A and 210B are the same, the volume of the second solder pattern 220BP is smaller than the volume of the first solder pattern 220AP.

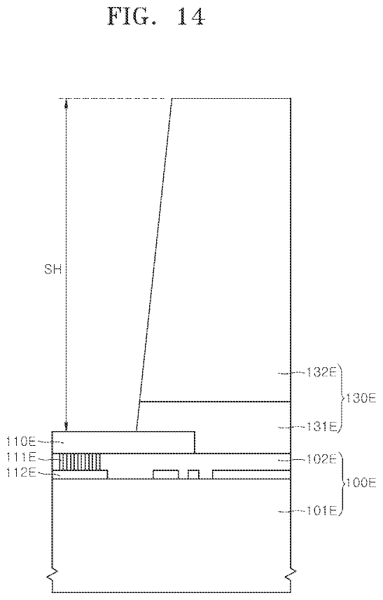

FIG. 14 is a cross-sectional view illustrating a semiconductor device according to an embodiment. Referring to FIG. 14, the semiconductor device includes a first substrate 100E, a conductive pad 110E, and a dielectric layer 130E. A plurality of conductive vias 111E are connected to the conductive pad 110E while supporting the conductive pad 110E. Conductive patterns 112E are disposed on an underlying layer 101E. The conductive patterns 112E may each be a metal wire. The conductive vias 111E are connected to the conductive pattern 112E and electrically connect the conductive pattern 112E and the conductive pad 110E.

The underlying layer 101E may include a semiconductor substrate in which an integrated circuit (not illustrated) is integrated. An insulating layer 102E that insulates the conductive patterns 112E and the conductive vias 111E is disposed between the underlying layer 101E and the conductive pad 110E. An additional insulating layer may be further disposed between the insulating layer 102E and the underlying layer 101E. Additional conductive patterns may be included in the interconnection wiring structure.

The dielectric layer 130E is disposed on the insulating layer 102E such that a section of the conductive pad 110E is exposed. The dielectric layer 130E may include a first dielectric layer 131E and a second dielectric layer 132E. The first dielectric layer 131E may be an inorganic insulating layer including a passivation material, such as silicon oxide or silicon nitride. The first dielectric layer is formed such that a section of the conductive pad 110E is exposed. The second dielectric layer 132E may include a carbon polymer insulating layer, such as PIQ. A step SH is formed between a top surface of the dielectric layer 130E (132E) and a top surface of the conductive pad 110E. A deviation between the heights of bumps attributable to the step SH may be compensated for by forming the first bump 200A of FIG. 1 on the conductive pad 110E and forming the second bump 200B of FIG. 1 on the dielectric layer 130E.

The embodiments of the present disclosure are described herein. A person having ordinary knowledge in the art to which the present disclosure pertains will understand that the present disclosure may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A semiconductor device comprising:
a first pillar and a second pillar formed over a substrate;
a first solder layer configured to cover a first surface of the first pillar; and
a second solder layer configured to cover a second surface of the second pillar;
wherein the first surface of the first pillar has a lower height than a height of the second surface of the second pillar and the second solder layer has a smaller thickness than a thickness of the first solder layer to compensate for a difference between a height of the second surface and a height of the first surface, wherein the first surface of the first pillar is a surface of the first pillar at a farthest distance from a surface of the substrate, and the second surface of the second pillar is a surface of the second pillar at a farthest distance from the surface the substrate.

2. The semiconductor device of claim 1, wherein:
a first height of the first surface of the first pillar is a first distance from a surface of the substrate, and a second height of the second surface of the second pillar is a second distance from the surface of the substrate, and
a first thickness of the first solder layer is a distance from the first surface to a first end of the first solder layer, and a second thickness of the second solder layer is a distance from the second surface to a second end of the second solder layer, wherein the first end of the first solder layer is an end of the first solder layer farthest from the first pillar, and the second end of the second solder layer is an end of the second solder layer farthest from the second pillar.

3. The semiconductor device of claim 1, wherein the substrate comprises a conductive pad connected to the first pillar.

4. The semiconductor device of claim 3, further comprising, on the substrate, a dielectric layer that exposes the conductive pad,
wherein the second pillar is disposed on the dielectric layer such that the second surface of the second pillar has a height greater than a height of the first surface of the first pillar by a thickness of the dielectric layer.

5. The semiconductor device of claim 4, further comprising:
a first underlying layer formed between the first pillar and the conductive pad; and
a second underlying layer formed between the second pillar and the dielectric layer.

6. The semiconductor device of claim 1, wherein the second pillar has a thickness identical to a thickness of the first pillar or has a thickness greater than the thickness of the first pillar.

7. The semiconductor device of claim 1, wherein the second pillar has a width identical to a width of the first pillar or has a width greater than the width of the first pillar.

8. A semiconductor device comprising:
a first substrate;
a second substrate that is disposed over the first substrate and that comprises a first conductive trace and a second conductive trace;
a first pillar and a second pillar disposed between the first substrate and the second substrate;
a first solder layer configured to cover a first surface of the first pillar; and
a second solder layer configured to cover a second surface of the second pillar;
wherein the first surface of the first pillar has a lower height than a height of the second surface of the second pillar, wherein the first surface of the first pillar is a surface of the first pillar at a farthest distance from a surface of the substrate, and the second surface of the second pillar is a surface of the second pillar at a farthest distance from the surface the substrate;
wherein the first solder layer is connected to the first conductive trace;
wherein the second solder layer is connected to the second conductive trace; and
wherein a distance between the first surface and the first conductive trace is greater than a distance between the second surface and the second conductive trace.

9. The semiconductor device of claim 8, wherein
the first substrate comprises a conductive pad connected to the first pillar;
wherein the semiconductor device further comprises, on the substrate, a dielectric layer that exposes the conductive pad; and
wherein the second pillar is disposed on the dielectric layer such that the second surface of the second pillar has a height greater than a height of the first surface of the first pillar by a thickness of the dielectric layer.

10. The semiconductor device of claim 9, wherein the first substrate further comprises:
conductive vias configured to support the conductive pad;
conductive patterns connected to the conductive pad by the conductive vias; and
an insulating layer configured to insulate the conductive vias and the conductive patterns;
wherein the dielectric layer comprises:
a first dielectric layer that exposes a section of the conductive pad and that comprises an inorganic insulating layer; and
a second dielectric layer that is disposed on the first dielectric layer and that comprises a carbon polymer insulating layer.

11. A method of manufacturing a semiconductor device, comprising:
forming a first pillar and a second pillar over a substrate;
forming a first resist pattern comprising a first opening that exposes a first surface of the first pillar and comprising a second opening that exposes a second surface of the second pillar and that has a smaller width than the width of the first opening, wherein the first surface of the first pillar is a surface of the first pillar at a farthest distance from a surface of the substrate, and the second surface of the second pillar is a surface of the second pillar at a farthest distance from the surface the substrate;
forming a first solder pattern within the first opening and a second solder pattern within the second opening;
removing the first resist pattern; and
forming a first solder layer by reflowing the first solder pattern and forming a second solder layer by reflowing the second solder pattern.

12. The method of claim 11, wherein the first pillar and the second pillar are formed such that the first surface of the first pillar has a lower height than the second surface of the second pillar.

13. The method of claim 12, wherein the second solder layer is formed having a smaller thickness than the first solder layer to compensate for a difference between a height of the second surface and a height of the first surface.

14. The method of claim 11, wherein the second solder pattern is formed having a smaller volume than the first solder pattern due to a difference between a width of the first opening and a width of the second opening.

15. The method of claim 11, wherein:
the substrate comprise a conductive pad, and
the first pillar is connected to the conductive pad.

16. The method of claim 15, further comprising forming, over the substrate, a dielectric layer that exposes the conductive pad,
wherein the second pillar is connected to the dielectric layer and formed such that the second surface of the second pillar has a height greater than a height of the first surface of the first pillar by a thickness of the dielectric layer.

17. The method of claim 16, wherein the forming the first pillar and the second pillar comprises:
forming a seed layer for plating, which covers the conductive pad and extends to cover the dielectric layer;
forming a second resist pattern comprising a third opening that overlaps the conductive pad and a fourth opening that overlaps the dielectric layer; and
plating the first pillar within the first opening, and plating the second pillar within the fourth openings.

18. The method of claim 11, wherein the first solder pattern is formed by plating a solder material within the first opening, and the second solder pattern is formed by plating a solder material within the second opening.

19. The method of claim 11, wherein the second pillar is formed having a thickness identical to a thickness of the first pillar or having a greater thickness than the thickness of the first pillar.

20. The method of claim 11, wherein the second pillar is formed having a width identical to a width of the first pillar or having a greater width than the width of the first pillar.

21. A semiconductor device comprising:
a first pillar and a second pillar formed over a substrate;
a first solder layer configured to cover a first surface of the first pillar; and
a second solder layer configured to cover a second surface of the second pillar;
wherein the second solder layer has a smaller thickness than a thickness of the first solder layer to compensate for a difference between a height of the second surface and a height of the first surface.
